(19) United States
(12) Patent Application Publication
(10) Pub. No.: US 2022/0416151 A1
(43) Pub. Date: Dec. 29, 2022

(54) ENERGY HARVESTING APPARATUS HAVING PIEZOELECTRIC ARMS

(71) Applicant: QPOWER LTD, ROSH HAAYIN (IL)

(72) Inventors: SHIMON PODVAL, RISHON LEZION (IL); GABRIEL SEIDEN, REHOVOT (IL); LIOR BLANKA, ROSH HAAYIN (IL)

(21) Appl. No.: 17/361,444

(22) Filed: Jun. 29, 2021

(51) Int. Cl. H01L 41/113; H02N 2/18

(52) U.S. Cl. CPC H01L 41/1136; H02N 2/186

(57) ABSTRACT

A device for harvesting motion energy, the device including an outer structure, a plurality of piezoelectric units including a permanent source of electromagnetic field (magnet or electret) attached to a piezoelectric material, where each of the piezoelectric units is fixed, at least in part, to the outer structure, an inner structure located inside the outer structure, the inner structure including a plurality of permanent sources of electromagnetic field (magnets or electrets) fixed to a rigid frame, the inner structure is configured to be suspended within the outer structure due to mutual electromagnetic forces acting between permanent sources of electromagnetic field pertaining to the piezoelectric units and permanent sources of electromagnetic field pertaining to the inner structure, and an electric circuit configured to store or provide electric energy supplied by the piezoelectric units due to strain caused by relative motion between the outer structure and the inner structure.

### FIELD

The subject matter described herein generally relates to harvesting energy, more specifically to harvesting energy by a device having piezoelectric arms.

### BACKGROUND

Energy harvesting systems convert ambient energy sources into accessible, stored energy in order to power electronic devices. Ambient energy sources may include solar energy, wind energy, thermal energy, kinetic (motion) energy and the like.

There is a growing interest in energy harvesting devices designed to power small, autonomous devices, such as wearable electronics, sensors, end-devices and the like. These wearable devices are typically powered by body motion, which has a characteristic frequency on the order of 1 Hz.

A prominent energy harvesting technology utilized for such wearable devices is based on piezoelectric energy harvesters (PZEH). Ideally, the resonance frequency of the harvester should match the characteristic frequency of the ambient motion in order to be efficient. In order to fulfill this requirement, current PZEH devices use a frequency-matching agent (also termed frequency-up-converter due to the relatively high resonance frequency of PZEH), such as multiple harvesting units (e.g., piezoelectric cantilevers) having varying natural frequencies. The need for frequency-matching agents usually results in a more complicated and expensive device. For example, in case of a device having multiple harvesting piezoelectric resonators, the resultant PZEH is larger and more expensive to produce due to the incorporation of the frequency-matching agent.

Yet another challenge in PZEH design relates to the fact that unlike ambient sources wherein there is a predetermined, well-defined orientation, in which the harvesting device needs to be aligned in order to have optimal performance, wearable devices may have arbitrary, spatially-dependent motion.

There is therefore a need to provide a PZEH-based method, system and device that is energy efficient, cost effective and spatially isotropic.

### SUMMARY

The subject matter described herein includes a PZEH device designed to harvest motion energy. The device comprises an outer structure, a plurality of piezoelectric harvesting units, each of the piezoelectric harvesting units comprises a piezoelectric transducer attached to a material having a permanently embedded static electromagnetic field, in the form of a permanent magnet or electret. The device also comprises an inner structure located inside the outer structure. The inner structure comprises a rigid frame and a plurality of either permanent magnets or electrets attached to the frame, and an electric circuit for storing the electric energy generated when the inner structure suspends within the outer structure in response to movement of the outer structure. The electric circuit may comprise a battery, battery, a super capacitor and the like. The electric circuit may include power management circuits or any other electrical components or circuits in a way that enables the usage of the harvested energy for powering electrical circuits or enables to store the harvested electric energy or to use the harvested energy for charging batteries or other energy storage entities.

The piezoelectric units are fixed to the outer structure walls. The piezoelectric units are spatially arranged so that the electromagnetic interaction between the set of magnets or electrets attached to the piezoelectric units and the set of magnets or electrets attached to the inner structure results in a zero net force on the inner structure.

Under no ambient motion the inner structure resides in a stable equilibrium position due to the confining electromagnetic forces. The stable equilibrium may be defined as a state in which the inner structure is not in physical contact with any of the walls of the outer structure. When ambient motion occurs, the outer structure moves in accordance with the ambient motion. However, the suspended inner structure moves due to an inertia-induced fictitious force, which is proportional to both the mass of the inner structure and to the instantaneous acceleration pertaining to the ambient motion of the outer structure. The direction of the fictitious force is opposite to the direction of the instantaneous acceleration pertaining to the ambient motion.

The motion of the inner structure causes the piezoelectric units to deform as a result of the dynamic electromagnetic interactions between the set of magnets or electrets attached to the moving inner structure and the set of magnets or electrets attached to the transducers of the piezoelectric units. This deformation excites the natural frequencies of the piezoelectric units. The energy associated with the resonating piezoelectric units is then harvested by the electric circuit. The excitation of the natural frequencies associated with the piezoelectric units is independent of the characteristic ambient motion frequency as well as of the spatial orientation of the motion.

The subject matter described herein also includes a device for harvesting motion energy, the device comprising: an outer structure; a plurality of piezoelectric units comprising a permanent source of electromagnetic field (magnet or electret) attached to a piezoelectric material; wherein each of said piezoelectric units is fixed, at least in part, to said outer structure; an inner structure located inside the outer structure, said inner structure comprising a plurality of permanent sources of electromagnetic field (magnets or electrets) fixed to a rigid frame; wherein said inner structure is configured to be suspended within said outer structure due to mutual electromagnetic forces acting between permanent sources of electromagnetic field (magnets or electrets) pertaining to said piezoelectric units and permanent sources of electromagnetic field (magnets or electrets) pertaining to said inner structure; an electric circuit configured to store or provide electric energy supplied by said piezoelectric units due to strain caused by relative motion between said outer structure and said inner structure.

In some cases, the piezoelectric units are in the form of cantilevers fixed at one end to the outer structure. In some cases, the device wherein comprises six piezoelectric units, wherein the outer structure comprising at least three perpendicular walls; wherein the inner structure has the form of a cube comprising six permanent sources of electromagnetic field (magnets or electrets) fixed within a solid frame; wherein each of said permanent sources of electromagnetic field (magnets or electrets) of the inner structure is facing one of the six piezoelectric units.

In some cases, the permanent sources of electromagnetic field pertaining to said piezoelectric units are permanent magnets having their north pole aligned towards said inner cube and the permanent sources of electromagnetic field pertaining to said inner structure are permanent magnets having their north pole aligned towards one of the six piezoelectric units.

In some cases, the permanent sources of electromagnetic field pertaining to said piezoelectric units are permanent magnets having their south pole aligned towards said inner cube and the permanent sources of electromagnetic field pertaining to said inner structure are permanent magnets having their south pole aligned towards one of the six piezoelectric units.

In some cases, the permanent sources of electromagnetic field pertaining to said piezoelectric units are electrets having the electric field aligned towards said inner cube and the permanent sources of electromagnetic field pertaining to said inner structure are electrets having their electric field aligned towards one of the six piezoelectric units.

In some cases, the permanent sources of electromagnetic field pertaining to said piezoelectric units are electrets having their electric field aligned opposite to said inner cube and the permanent sources of electromagnetic field pertaining to said inner structure are electrets having their electric field aligned opposite to one of the six piezoelectric units.

In some cases, the inner structure is a polytope having multiple sides, wherein the multiple magnetic or electrets are located on at least three of the multiple sides of the inner structure.

In some cases, at least two of the multiple sides of the inner structure are opposite sides. In some cases, the multiple magnetic or electrets are removable from the inner structure. In some cases, the electric circuit comprises means to store the electric energy. In some cases, the inner structure resides in a stable equilibrium in the outer structure when the outer structure does not move. In some cases, the device is a wearable device.

In some cases, the plurality of piezoelectric units are spatially arranged in the outer structure such that the electromagnetic field between the permanent sources of electromagnetic field pertaining to the piezoelectric units and the permanent sources of electromagnetic field pertaining to the inner structure results in a zero net force on the inner structure when the outer structure does not move. In some cases, the plurality of piezoelectric arms deforms in response to movement of the inner structure relative to the plurality of piezoelectric arms. In some cases, the inner structure is made of metallic material.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 shows a perspective view including the internal parts of the device for harvesting energy, according to exemplary embodiments of the invention.

FIG. 2 shows a perspective view of a single piezoelectric unit, according to exemplary embodiments of the invention.

FIG. 3 shows a perspective view of the inner structure, according to exemplary embodiments of the invention.

FIG. 4 shows a Perspective view of the magnets within the inner structure, according to exemplary embodiments of the invention.

FIG. 5 shows a high level block diagram view of an energy harvesting circuit, according to exemplary embodiments of the invention.

### DETAILED DESCRIPTION

The following detailed description makes reference to the accompanying drawings, which form a part hereof. The illustrative description and specific examples of the embodiments are not meant to be limiting.

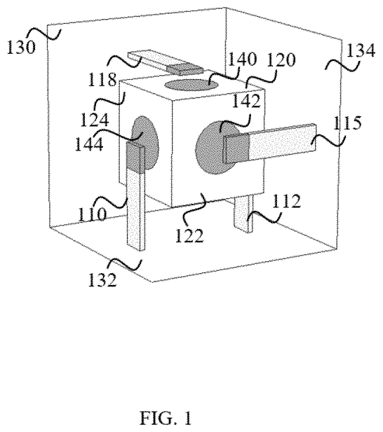

FIG. 1 shows a perspective view including the internal parts of the device for harvesting energy, according to exemplary embodiments of the invention.

The device comprising piezoelectric units 110, 112, 115, 118. The number of piezoelectric units used by the device may vary, and be selected by a person skilled in the art. FIG. 1 shows an exemplary embodiment, in which the device comprises six (6) identical cantilever-shaped piezoelectric units. The device also comprises a cubical-shaped inner structure and an outer structure.

The outer structure is defined by sidewalls having an internal surface and an external surface. The outer structure may be sealed, preventing liquid to flow and touch the inner structure. The outer structure may surround the entirety of the inner structure. The outer structure may comprise voids enabling passage of air into the volume defined between the walls of the outer structure. The outer structure may comprise an aperture enabling to insert a cable to collect the electric energy stored in the electrical circuit, in case the electrical circuit is located inside the outer structure.

The shape of the outer structure may be defined by walls 130, 132, 134 forming the outer structure. The walls may be flat, defined as all regions in the wall point towards the same direction. In some other cases, at least a portion of the walls may be elliptical. The external surface of the walls of the outer structure may be accessed to a person, for example in order to secure the outer structure to another object.

The piezoelectric units 110, 112, 115, 118 are physically secured to the inner surface of the walls assembling the outer structure. For example, piezoelectric units 110 and 112 are secured to wall 132, piezoelectric unit 118 is secured to wall 130 and piezoelectric unit 115 is secured to wall 134. piezoelectric units 110, 112, 115, 118 may be secured to the walls assembling the outer structure using adhesive materials, by welding, or using any other technique selected by a person skilled in the art.

The device also comprises an inner structure located in its entirety inside the outer structure. The inner structure comprises walls 120, 122, 124, defining the shape of the inner structure. The walls 120, 122, 124 may be flat, elliptical, or a combination thereof. At least a portion of the walls 120, 122, 124 are coupled to electromagnetic units 140, 142, 144, which may be magnets or electrets. In some exemplary cases, every wall of the inner structure may be coupled to a single electromagnetic unit. For example, wall 120 is coupled to electromagnetic unit 140, wall 122 is coupled to electromagnetic unit 142 and wall 124 is coupled to electromagnetic unit 144.

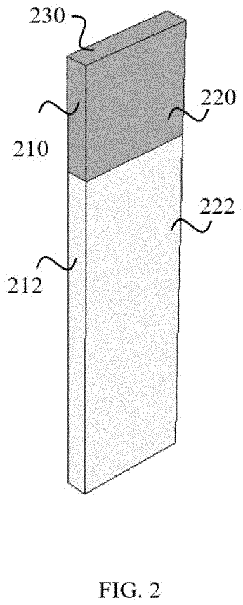

FIG. 2 shows a single cantilever-shaped piezoelectric unit. According to one embodiment, the unit comprises a piezoelectric element connected at its distal section to a permanent magnet. The piezoelectric unit is configured to be fixed at its base to a wall of the outer structure. The distal section is the area of the piezoelectric unit located away from the wall of the outer structure. The permanent magnet may have a wide surface 220 and a narrow surface 210, depending on the shape of the piezoelectric unit. In some cases, the piezoelectric unit is coupled to the walls of the outer structure such that the wide surface 220 is parallel to the electromagnetic unit (such as units 140, 142, 144) of the inner structure.

The piezoelectric unit may also be defined by a top surface 230, which is the farthest point from the inner wall of the outer structure to which piezoelectric unit is coupled. The piezoelectric unit also comprises a non-magnetic part, defined by a wide surface 222 and a narrow surface 212.

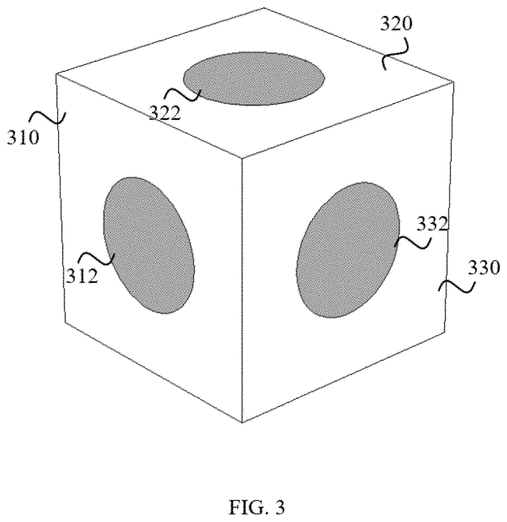

FIG. 3 shows the inner structure of the device, according to exemplary embodiments of the invention. The inner structure shown in FIG. 3 is of a cube-shape, comprising six permanent magnets fixed within a solid frame. The cube-shape comprises surfaces forming the frame, from which surfaces 310, 320 and 330 can be seen. Surface 310 is coupled to magnet 312, surface 320 is coupled to magnet 322 and surface 330 is coupled to magnet 332.

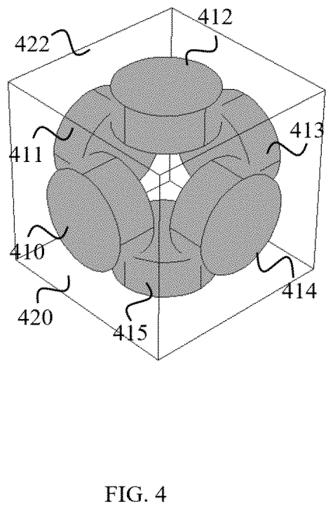

FIG. 4 shows the inner structure of the device with the magnets having a circular cross section, according to exemplary embodiments of the invention. Each magnet 410, 411, 412, 413, 414, 415 is placed with its symmetry axis aligned with one of the main axes of the cube. The main axes are aligned to the surface of the walls 420, 422 assembling the cube. The external face of the magnet coincides with one of the six cube faces. The frame of the inner structure may be of metal consistency in order to maximize the mass of the inner structure. The larger the mass of the inner structure, the more energy can be harvested from the device.

The six cantilever-shaped piezoelectric units may be arranged in three pairs, to match the arrangement of the magnets 410, 411, 412, 413, 414, 415. Each pair of piezoelectric units may then be fixed to one of three walls of the outer structure. The cantilever-shaped piezoelectric units within a pair are positioned parallel to each other, each piezoelectric unit in a pair is facing an opposing face of the inner cube. The distance between the two cantilever-shaped piezoelectric units within a pair is greater than the length of a side of the inner structure cube and allows for sufficient space for motion of both the cantilever tip and the suspended inner cube (see FIG. 1).

According to one exemplary embodiment, the six magnets embedded in the cube-shaped inner structure have their north pole facing the outer face of the cube and the six magnets pertaining to the piezoelectric units have their north pole facing the inner cube. In this way, there is a repulsive force between neighboring magnets from the two sets, the first set is of the piezoelectric units and the second set is coupled to the inner structure. The repulsive force increases as the distance between the neighboring magnets decreases. This results in a non-contact interaction between the cube and the cantilever during the inner cube dynamics induced by the ambient motion.

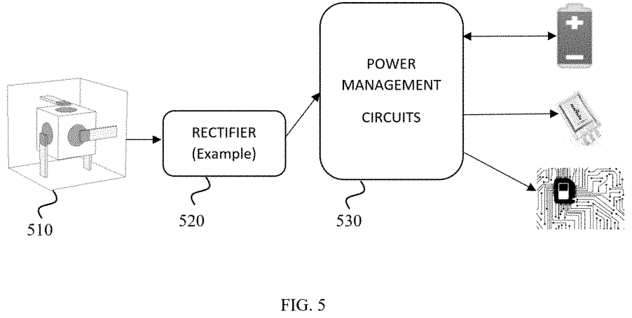

FIG. 5 shows an energy harvesting system diagram, according to exemplary embodiments of the invention. The diagram shows options of a power management circuit 530, such as a battery, a super capacitor or an electronic circuit to the device for harvesting energy 510. The system may also comprise a rectifier 520, coupled to both the device for harvesting energy 510 and to the power management circuit 530. The electrical circuit may be part of frame, and/or the inner structure or attached to the frame or even connected with wires from the outside the outer structure. In some cases, one part of the electrical circuit may be placed inside the outer structure and another part of the electrical circuit may be placed outside the outer structure.

Although the invention has been described in conjunction with specific embodiments thereof, it is evident that many alternatives, modifications, and variations will be apparent to those skilled in the art. Accordingly, it is intended to embrace all such alternatives, modifications and variations.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the invention. To the extent that section headings are used, they should not be construed as necessarily limiting.

What is claimed is:

1. A device for harvesting motion energy, the device comprising:
an outer structure;
a plurality of piezoelectric units comprising a permanent source of electromagnetic field (magnet or electret) attached to a piezoelectric material, wherein each of said piezoelectric units is fixed, at least in part, to said outer structure;
an inner structure located inside the outer structure, said inner structure comprising a plurality of permanent sources of electromagnetic field (magnets or electrets) fixed to a rigid frame, wherein said inner structure is configured to be suspended within said outer structure due to mutual electromagnetic forces acting between permanent sources of electromagnetic field (magnets or electrets) pertaining to said piezoelectric units and permanent sources of electromagnetic field (magnets or electrets) pertaining to said inner structure; and
an electric circuit configured to store or provide electric energy supplied by said piezoelectric units due to strain caused by relative motion between said outer structure and said inner structure.

2. The device of claim 1, wherein the piezoelectric units are in the form of cantilevers fixed at one end to the outer structure.

3. The device of claim 2, wherein
the plurality of piezoelectric units includes six piezoelectric units,
the outer structure comprising at least three perpendicular walls,
the inner structure has the form of a cube comprising six permanent sources of electromagnetic field (magnets or electrets) fixed within a solid frame, and
each of said permanent sources of electromagnetic field (magnets or electrets) of the inner structure is facing one of the six piezoelectric units.

4. The device of claim 3, wherein the permanent sources of electromagnetic field pertaining to said piezoelectric units are permanent magnets having their north pole aligned towards said inner cube and the permanent sources of electromagnetic field pertaining to said inner structure are permanent magnets having their north pole aligned towards one of the six piezoelectric units.

5. The device of claim 3, wherein the permanent sources of electromagnetic field pertaining to said piezoelectric units are permanent magnets having their south pole aligned towards said inner cube and the permanent sources of electromagnetic field pertaining to said inner structure are permanent magnets having their south pole aligned towards one of the six piezoelectric units.

6. The device of claim 3, wherein the permanent sources of electromagnetic field pertaining to said piezoelectric units are electrets having the electric field aligned towards said inner cube and the permanent sources of electromagnetic field pertaining to said inner structure are electrets having their electric field aligned towards one of the six piezoelectric units.

7. The device of claim 3, wherein the permanent sources of electromagnetic field pertaining to said piezoelectric units are electrets having their electric field aligned opposite to said inner cube and the permanent sources of electromagnetic field pertaining to said inner structure are electrets having their electric field aligned opposite to one of the six piezoelectric units.

8. The device of claim 1, wherein the inner structure is a polytope having multiple sides, wherein the multiple magnetic or electrets are located on at least three of the multiple sides of the inner structure.

9. The device of claim 8, wherein at least two of the multiple sides of the inner structure are opposite sides.

10. The device of claim 1, wherein the multiple magnetic or electrets are removable from the inner structure.

11. The device of claim 1, wherein the electric circuit comprises means to store the electric energy.

12. The device of claim 1, wherein the inner structure resides in a stable equilibrium in the outer structure when the outer structure does not move.

13. The device of claim 1, wherein the device is a wearable device.

14. The device of claim 1, wherein the plurality of piezoelectric units are spatially arranged in the outer structure such that the electromagnetic field between the permanent sources of electromagnetic field pertaining to the piezoelectric units and the permanent sources of electromagnetic field pertaining to the inner structure results in a zero net force on the inner structure when the outer structure does not move.

15. The device of claim 1, wherein the plurality of piezoelectric arms deforms in response to movement of the inner structure relative to the plurality of piezoelectric arms.

16. The device of claim 1, wherein the inner structure is made of metallic material.
